(19) United States
(12) Patent Application Publication
(10) Pub. No.: US 2012/0275091 A1
(43) Pub. Date: Nov. 1, 2012

(54) ELECTRONIC DEVICE

(75) Inventors: Chun-Hsiung Yin, Taipei (TW); Chun-Chi Lin, Taipei (TW); Liang-Chieh Tseng, Taipei (TW)

(73) Assignee: INVENTEC CORPORATION, Taipei (TW)

(21) Appl. No.: 13/170,356

(22) Filed: Jun. 28, 2011

(30) Foreign Application Priority Data
Apr. 29, 2011 (TW) 100115266

(51) Int. Cl. H05K 5/00

(52) U.S. Cl. 361/679.01

(57) ABSTRACT

An electronic device includes a first shell body, a second shell body, and a third shell body. A second side edge of the second shell body is pivotally disposed at a first side edge of the first shell body, and the second shell body pivotally rotates relative to the first shell body in a first axial direction. A third surface of the third shell body is attached to and pivotally disposed at a second surface of the second shell body. The third shell body pivotally rotates relative to the second shell body in a second axial direction, and the second axial direction intersects the first axial direction. Accordingly, the electronic device presents two use types for convenient use.

### CROSS-REFERENCE TO RELATED APPLICATIONS

This non-provisional application claims priority under 35 U.S.C. §119(a) on Patent Application No(s). 100115266 filed in Taiwan, R.O.C. on Apr. 29, 2011, the entire contents of which are hereby incorporated by reference.

### BACKGROUND

1. Field

The present disclosure relates to an electronic device, and more particularly to a mobile electronic device.

2. Related Art

In recent years, due to the fast development of science and technology, electronic products already become indispensable in the lives of modern people. All things in the daily life gradually develop to be electronic and digital. As for a work type, the time consuming document processing on papers in the early days develop into more efficient document processing by using computers nowadays. Therefore, the computer is an important device that has changed the life type of human beings.

The large-volume desktop computer in the early days develops into the portable personal notebook computer nowadays. Further, for the light and thin characteristics of the personal notebook computer, in the current society, almost every one owns a notebook computer. With the notebook computer, a user can perform document processing, or enjoy the multimedia entertainment. In addition, due to the miniaturization trend of the electronic product, in recent years, the light and thin tablet computer adopting a touch screen becomes available in the market. The tablet computer has a simple and clear appearance and a touch operation mode, thereby becoming very popular among a large number of users. However, although the tablet computer is easily operable and portable, the tablet computer itself is not provided with a physical keyboard structure. Therefore, when the user performs document processing with the tablet computer, the text input part becomes very inconvenient. An additional physical keyboard being assembled on the tablet computer makes it very convenient for the user to input text, but the additional physical keyboard also causes poor portability for the user.

Accordingly, at present, none of the commercially available electronic products has both the advantages of the simple and clear appearance and the touch operation mode of the tablet computer and the advantage of being provided with the physical keyboard facilitating the document processing of the notebook computer.

### SUMMARY

In view of the above problems, the present disclosure is an electronic device, which has both use types of the tablet computer and the notebook computer, so as to achieve the use convenience for the user.

The present disclosure provides an electronic device, which comprises a first shell body, a second shell body, and a third shell body. The first shell body has a first side edge, and the second shell body has a second surface and a second side edge. The second side edge of the second shell body is pivotally disposed at the first side edge of the first shell body, and the second shell body pivotally rotates relative to the first shell body in a first axial direction, the first axial direction is an extending direction of the first side edge and the second side edge. The third shell body has a third surface, and the third surface of the third shell body is attached to and pivotally disposed at the second surface of the second shell body. The third shell body pivotally rotates relative to the second shell body in a second axial direction, the second axial direction is a direction of a normal vector of the second surface, and the second axial direction intersects the first axial direction.

According to the electronic device provided in the present disclosure, the first side edge of the first shell body is pivotally disposed at the second side edge of the second shell body, so the second shell body pivotally rotates relative to the first shell body in the first axial direction. The third surface of the third shell body is attached to and pivotally disposed at the second surface of the second shell body, so the third shell body pivotally rotates relative to the second shell body in the second axial direction intersecting the first axial direction. Accordingly, the electronic device presents a first use state and a second use state for the use convenience of the user.

### BRIEF DESCRIPTION OF THE DRAWINGS

The accompanying drawings illustrate one or more embodiments of the disclosure and, together with the written description, serve to explain the principles of the disclosure. Wherever possible, the same reference numbers are used throughout the drawings to refer to the same or like elements of an embodiment, and wherein:

FIG. 1A is a schematic assembly structural view of an electronic device according to an embodiment of the present disclosure;

FIG. 1B is a schematic exploded structural view of an electronic device according to an embodiment of the present disclosure; and

FIGS. 2A to 2C are schematic views of an electronic device being switched from a first use type into a second use type according to an embodiment of the present disclosure.

### DETAILED DESCRIPTION

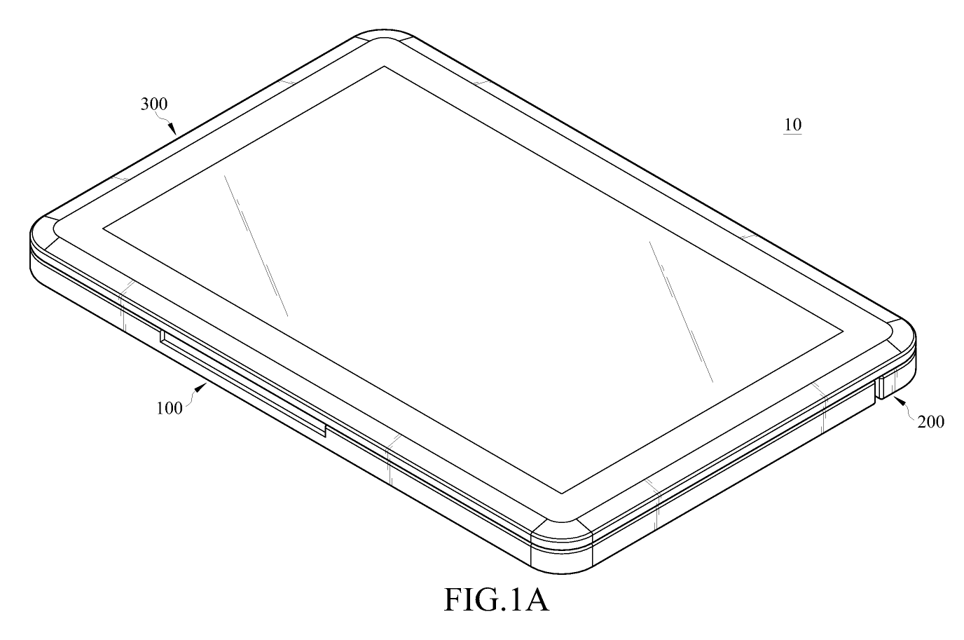

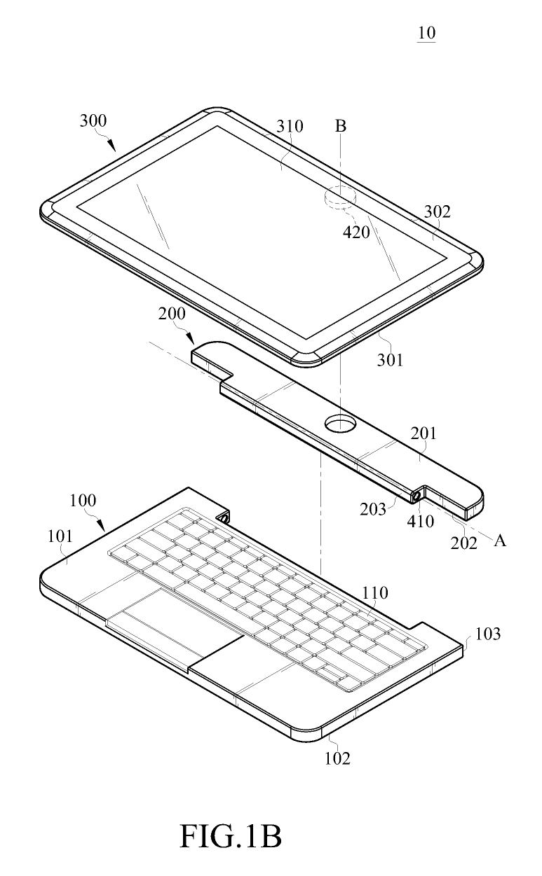

Referring to both FIGS. 1A and 1B, FIG. 1A is a schematic assembly structural view of an electronic device according to an embodiment of the present disclosure, and FIG. 1B is a schematic exploded structural view of an electronic device according to an embodiment of the present disclosure.

A portable mobile electronic device may be taken as an example for the electronic device 10 in this embodiment, for example, a portable personal computer, but the present disclosure is not limited thereto. For example, the electronic device 10 may also be a personal mobile phone.

The electronic device 10 in this embodiment comprises a first shell body 100, a second shell body 200, and a third shell body 300. The first shell body 100 is generally a rectangular tablet body, and first shell body 100 has a first side edge 103 as well as a first surface 101 and a sixth surface 102 opposite to each other. Further, the electronic device 10 further comprises a keyboard 110, the keyboard 110 has a plurality of physical keys, and the keyboard 110 is disposed on the first surface 101.

The second shell body 200 is generally a rectangular tablet body, the second shell body 200 has a length and a thickness approximately the same as those of the first shell body 100, and the second shell body 200 has a width smaller than that of the first shell body 100. The second shell body 200 has a second side edge 203 as well as a second surface 201 and a fifth surface 202 opposite to each other. The second side edge 203 of the second shell body 200 may be pivotally disposed at the first side edge 103 of the first shell body 100 through a first pivot 410. The second shell body 200 may pivotally rotate relative to the first shell body 100 in a first axial direction A, and the first axial direction A is an extending direction of the first side edge 103 and the second side edge 203. Further, when the second shell body 200 pivotally rotates relative to the first shell body 100 in the first axial direction A, an included angle between the second surface 201 and the first surface 101 keeps changing.

The third shell body 300 in this embodiment is generally a rectangular tablet body, the third shell body 300 has a length and a thickness approximately the same as those of the first shell body 100 or the second shell body 200, and the width of the third shell body 300 approximately equals a sum of the widths of the first shell body 100 and the second shell body 200. The third shell body 300 has a third surface 301 and a fourth surface 302 opposite to each other. Further, the electronic device 10 further comprises a screen 310, the screen 310 may be a touch screen, and the screen 310 is disposed on the fourth surface 302. The third surface 301 of the third shell body 200 may be pivotally disposed at the second surface 201 of the second shell body 200 through a second pivot 420, and the third surface 301 is permanently attached to the second surface 201. The third shell body 300 may pivotally rotate relative to the second shell body 200 in a second axial direction B, and the second axial direction B is a direction of a normal vector of the third surface 301 or a normal vector of the second surface 201. Furthermore, when the third shell body 300 pivotally rotates relative to the second shell body 200 in the second axial direction B, the third surface 301 is kept being attached to the second surface 201.

Furthermore, the first axial direction A is different from the second axial direction B, and the first axial direction A and the second axial direction B are approximately perpendicular to each other.

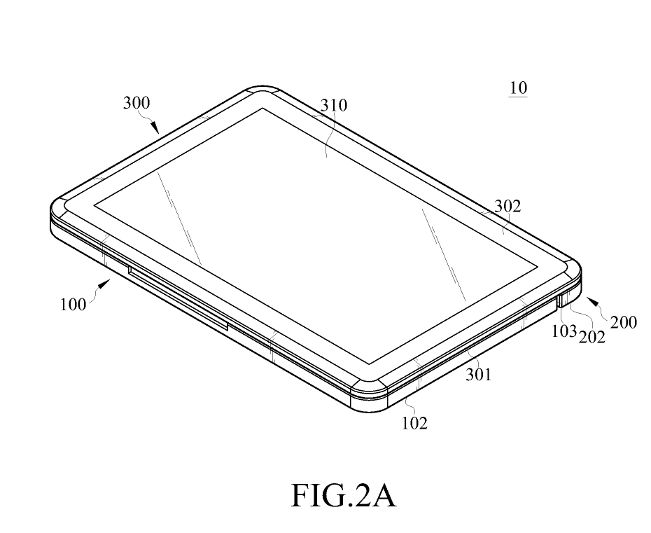

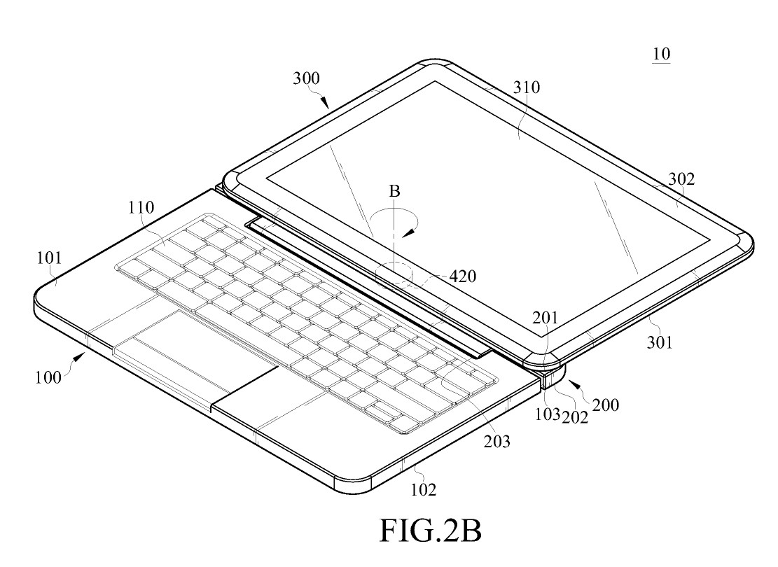

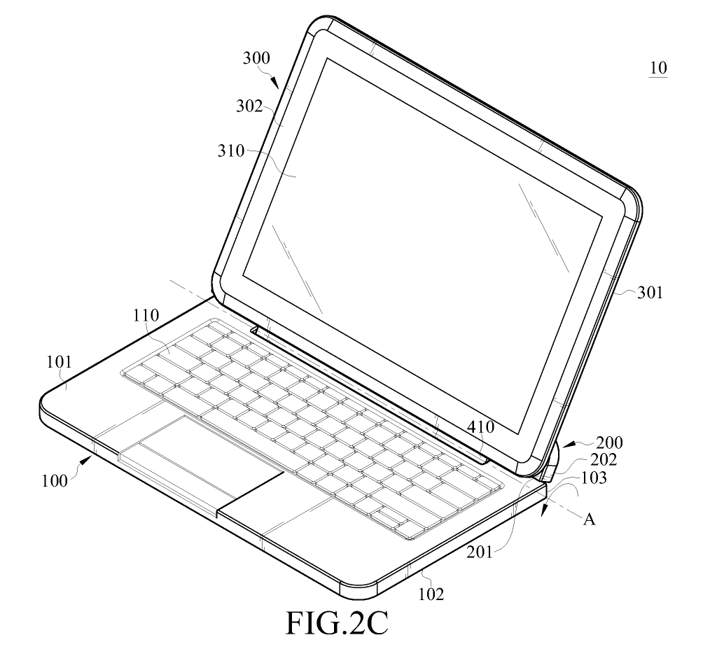

Referring to FIGS. 2A to 2C in combination with FIG. 1B, FIGS. 2A to 2C are schematic views of an electronic device being switched from a first use type into a second use type according to an embodiment of the present disclosure.

The electronic device 10 in this embodiment has a first use type (as shown in FIG. 2A) and a second use type (as shown in FIG. 2C). When the electronic device 10 is in the first use type, the electronic device 10 has an aspect and an operation mode of a common tablet computer. When the electronic device 10 is in the second use type, the electronic device 10 has an aspect and an operation node of a common notebook computer.

Specifically, when the electronic device 10 is in the first use type, the normal vector of the second surface 201 of the second shell body 200 has the same direction as the normal vector of the first surface 101 of the first shell body 100. In other words, the second surface 201 and the first surface 101 approximately present a coplanar state. Further, the third surface 301 of the third shell body 300 is attached to the second surface 201 of the second shell body 200 and the first surface 101 of the first shell body 100 at the same time. Further, the second surface 201 and the first surface 101 are covered and shielded by the third surface 301 at the same time. In other words, the third shell body 300 is stacked above the first shell body 100 and the second shell body 200, and the third shell body 300 shields the first shell body 100 and the second shell body 200. At this time, the keyboard 110 is covered and shielded by the third shell body 300 at the same time, and the fourth surface 302 of the third shell body 300 and the sixth surface 102 of the first shell body 100 are located at opposite two sides of the electronic device 10 in the first use type. Therefore, when the electronic device 10 is in the first use type, the keyboard 110 is shielded and only the screen 310 is exposed, so the electronic device 10 presents an aspect and an operation mode of the tablet computer.

When the user intends to switch the electronic device 10 from the first use type into the second use type in which the text input is convenient, the third shell body 300 is made to rotate 180 degrees relative to the second shell body 200 (as shown in FIG. 2B). At this time, the third shell body 300 no longer shields the first surface 101 of the first shell body 100, and the keyboard 110 on the first surface 101 is made to be not shielded by the third shell body 300 and then exposed. At this time, the normal vector of the fourth surface 302 has the same direction as the normal vector of the first surface 101.

Next, the second shell body 200 is made to pivotally rotate towards the first surface 101 of the first shell body 100 relative to the first shell body 100, so as to at the same time actuate the third shell body 300 to pivotally rotate relative to the first shell body 100 to form an angle between the fourth surface 302 and the first surface 101 (as shown in FIG. 2C). At this time, the electronic device 10 is switched into the second use type and presents that the third shell body 300 stands at a side of the first surface 101 of the first shell body 100, and the keyboard 110 is not shielded and then exposed, so that the electronic device 10 presents a use aspect and an operation mode of the notebook computer.

According to the electronic device in the above embodiments, the first side edge of the first shell body is pivotally disposed at the second side edge of the second shell body, so the second shell body pivotally rotates relative to the first shell body in the first axial direction. The third surface of the third shell body is attached to and pivotally disposed at the second surface of the second shell body, so that the third shell body pivotally rotates relative to the second shell body in the second axial direction intersecting the first axial direction. Accordingly, the third shell body having the screen of the electronic device may cover the keyboard to present a first use state of the aspect of the tablet computer, or the keyboard of the electronic device is exposed and an angle is formed between the keyboard and the screen, so as to present a second use state of the aspect of the notebook computer.

What is claimed is:

1. An electronic device, comprising:
a first shell body, having a first side edge;
a second shell body, having a second surface and a second side edge, wherein the second side edge of the second shell body is pivotally disposed at the first side edge of the first shell body, the second shell body pivotally rotates relative to the first shell body in a first axial direction, and the first axial direction is an extending direction of the first side edge and the second side edge; and
a third shell body, having a third surface, wherein the third surface of the third shell body is attached to and pivotally disposed at the second surface of the second shell body, and the third shell body pivotally rotates relative to the second shell body in a second axial direction, the second axial direction is a direction of a normal vector of the second surface, and the second axial direction intersects the first axial direction.

2. The electronic device according to claim 1, wherein the first shell body has a first surface, the third shell body has a fourth surface, the third surface and the fourth surface are located at two opposite sides of the third shell body, the electronic device has a first use type and a second use type, in the first use type, the third surface is attached to and shields the first surface and the second surface, when the electronic device is unfolded from the first use type into the second use type, the third shell body rotates 180 degrees relative to the second shell body to expose the first surface, and the second shell body rotates relative to the first shell body to form an angle between the fourth surface and the first surface.

3. The electronic device according to claim 2, further comprising a keyboard, located on the first surface.

4. The electronic device according to claim 2, further comprising a screen, located on the fourth surface.
